(19) United States
(12) Patent Application Publication
(10) Pub. No.: US 2009/0139657 A1
(43) Pub. Date: Jun. 4, 2009

(54) ETCH SYSTEM

(75) Inventors: CHANGHUN LEE, San Jose, CA (US); Brad Eaton, Menlo Park, CA (US); Diana X. Ma, Saratoga, CA (US)

Correspondence Address: TOWNSEND AND TOWNSEND AND CREW LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 12/207,815

(22) Filed: Sep. 10, 2008

Related U.S. Application Data
(60) Provisional application No. 60/992,283, filed on Dec. 4, 2007.

(51) Int. Cl. H01L 21/306

(52) U.S. Cl. 156/345.24

(57) ABSTRACT

A semiconductor processing system includes a factory interface. A central transfer chamber is coupled to the factory interface. A first number of etch chambers are coupled to the central transfer chamber. The first number of etch chambers are configured to etch a substrate at about a first processing time. A second number of post-etch treatment chambers are coupled to the central transfer chamber. The second number of post-etch treatment chambers are configured to process the substrate at about a second processing time, wherein a ratio of the first number to the second number is substantially proportional to a ratio of the first processing time to the second processing time.

### CROSS-REFERENCES TO RELATED APPLICATIONS

The present application claims benefit under 35 USC 119(e) of U.S. provisional Application No. 60/992,283 filed on Dec. 4, 2007, entitled “Etch System,” the content of which is incorporated herein by reference in its entirety. This application is related to co-assigned U.S. Patent Publication No. 2006/0289384 to Pavel et al, filed Aug. 28, 2006, and entitled “METHOD AND APPARATUS FOR PERFORMING HYDROGEN OPTICAL EMISSION ENDPOINT DETECTION FOR PHOTORESIST STRIP AND RESIDUE REMOVAL.” This application is also related to co-assigned U.S. Patent Publication No. 2007/0077767 to Jin et al., filed Aug. 14, 2006, and titled “METHOD OF PLASMA ETCHING OF HIGH-K DIELECTRIC MATERIALS.” The entire contents of both related applications are hereby incorporated by reference for all purposes.

### BACKGROUND

Embodiments of the present invention relate in general to semiconductor processing systems and in particular to etch systems used to process semiconductor wafers.

With advances in electronic products, semiconductor technology has been widely applied in manufacturing memories, central processing units (CPUs), liquid crystal displays (LCDs), light emission diodes (LEDs), laser diodes and other devices or chip sets. In order to achieve high-integration and high-speed requirements, dimensions of semiconductor integrated circuits have been reduced, and various materials and techniques have been proposed to achieve these requirements and overcome obstacles during manufacturing. In addition to these requirements, manufacturers of semiconductor integrated circuits have imposed requirements of high throughput, high volumes and low down time on equipment used to manufacture their semiconductor integrated circuits.

For example, semiconductor manufacturers have increased wafer dimensions, such as 12-inch wafers, to increase the production of integrated circuits. Manufacturers of integrated circuits also increase the number of facilities or equipment to enhance the number of wafers or chips that are fabricated monthly or annually. In addition, chip manufacturers also modify manufacturing processes to achieve goals of wafer throughputs.

Generally, wafers are subjected to various semiconductor processes, such as thin film depositions, etches, photolithography and thermal treatments. For example, a material layer formed over a wafer is subjected to an etch process by using a photoresist layer as a hard mask. After the etch process, a removing process is carried out to remove the photoresist layer. Then, a cleaning process is performed to remove residues of the photoresist layer or particles over the wafer. The etch process, the photoresist removing process and the cleaning process have different processing times.

Although many, if not all of these different processes, are performed on a single wafer when making an integrated circuit, the processes are often carried out in different tools that have not been configured to operate efficiently between each other. Therefore, what is needed is a system and method for efficiently operating two or more of the processes used to manufacture an integrated circuit so that both processes can produce integrated circuits with high tolerances and still have high throughput and process a high volume of wafers.

### BRIEF SUMMARY

According to embodiments of the present invention, a semiconductor processing system includes a factory interface, a central transfer chamber, a first number of etch chambers, and a second number of post-etch treatment chambers. The factory interface is coupled to the transfer chamber and the transfer chamber is coupled to the first number of etch chambers and the second number of post-etch treatment chambers. The first number of etch chambers are configured to etch a substrate at about a first processing time. The second number of post-etch treatment chambers are configured to process the substrate at about a second processing time. The ratio of the first number to the second number is substantially proportional to a ratio of the first processing time to the second processing time.

According to another embodiment of the present invention, the semiconductor processing system further includes at least one robot configured to transfer the substrate between the factory interface and the transfer chamber.

According to the other embodiment of the present invention, a vacuum level within the central transfer chamber is maintained at substantially the same vacuum level as either the etch chambers or the post-etch treatment chambers.

According to an alternative embodiment of the present invention, the first number of etch chambers is 3 and the second number of post-etch treatment chambers is 2.

According to an embodiment of the present invention, the first processing time is between about 75 seconds and about 225 seconds and the second processing time is between about 50 seconds and about 150 seconds.

According to another embodiment of the present invention, the etch chamber are metal etch chambers.

According to the other embodiment of the present invention, the post-etch treatments chambers are configured to remove at least one of photoresist, etch residues and etch by-product.

According to an alternative embodiment of the present invention, the etch chambers are configured to clean the substrate.

According to another embodiment of the present invention, a time for cleaning the substrate is between about 50 seconds and about 150 seconds.

According to other embodiments of the present invention, a semiconductor processing system includes a factory interface, a central transfer chamber, at least one robot, a first number of metal etch chambers, and a second number of post-etch treatment chambers. The factory interface is coupled to the transfer chamber and the transfer chamber is coupled to the first number of metal etch chambers and the second number of post-etch treatment chambers. The at least one robot is configured to transfer a substrate between the factory interface and the transfer chamber. The first number of metal etch chambers are configured to etch a substrate at about a first processing time. The second number of post-etch treatment chambers are configured to process the substrate at about a second processing time. The ratio of the first number of metal etch chambers to the second number post-etch treatment chambers is substantially proportional to a ratio of the first processing time to the second processing time.

According to other embodiments of the present invention, a semiconductor processing system includes a factory interface, a central transfer chamber, at least one robot, three metal etch chambers, and two post-etch treatment chambers. The factory interface is coupled to the transfer chamber and the transfer chamber is coupled to the three metal etch chambers and the two post-etch treatment chambers. The at least one robot is configured to transfer a substrate between the factory interface and the transfer chamber. The three metal etch chambers are configured to etch a substrate at about a first processing time. The two post-etch treatment chambers are configured to process the substrate at about a second processing time. The ratio of the first processing time to the second processing time is approximately 3 to 2.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sub-label is associated with a reference numeral and follows a hyphen to denote one of multiple similar components. When reference is made to a reference numeral without specification to an existing sub-label, it is intended to refer to all such multiple similar components.

FIG. 1 is a schematic drawing of an exemplary semiconductor processing system, in accordance with one embodiment of the invention;

FIG. 2 is a schematic top view of the exemplary semiconductor processing system of FIG. 1, in accordance with one embodiment of the invention;

FIG. 3 depicts a schematic diagram of the etch process chamber shown in FIG. 1, in accordance with an embodiment of the invention;

FIG. 4 depicts a schematic diagram of the post-etch treatment chamber shown in FIG. 1, in accordance with an embodiment of the invention;

FIGS. 5A-5B illustrate a flowchart of a method of processing a substrate within an etching system according to an embodiment of the invention; and

FIGS. 6A-6B illustrate a flowchart showing an exemplary sequence of an etching system according to an embodiment of the invention.

### DETAILED DESCRIPTION

Semiconductor processing systems are described for achieving a desired process efficiency and/or substrate throughputs.

According to embodiments of the present invention, a semiconductor processing system includes a factory interface, a central transfer chamber, a first number of etch chambers, and a second number of post-etch treatment chambers. The factory interface is coupled to the transfer chamber and the transfer chamber is coupled to the first number of etch chambers and the second number of post-etch treatment chambers. The first number of etch chambers are configured to etch a substrate at about a first processing time. The second number of post-etch treatment chambers are configured to process the substrate at about a second processing time. The ratio of the first number to the second number is substantially proportional to a ratio of the first processing time to the second processing time.

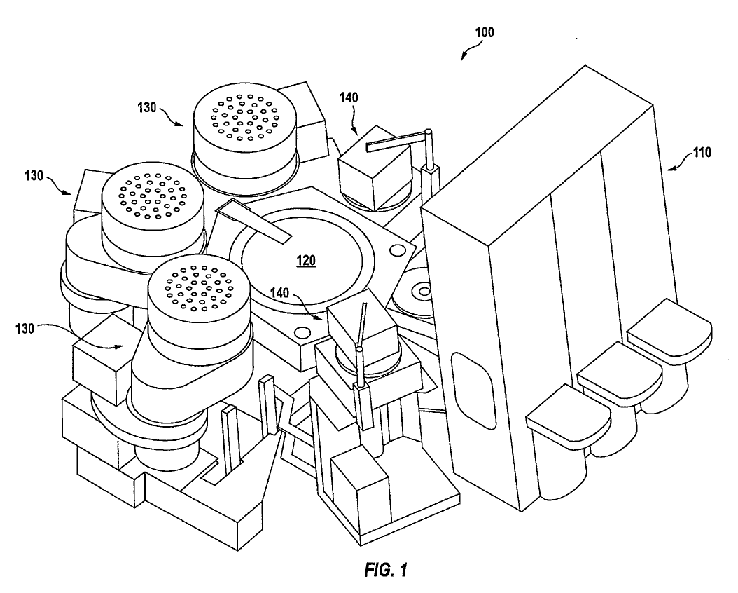

FIG. 1 is a schematic drawing of an exemplary semiconductor processing system 100 used to both etch substrates and then perform post-etch treatment on the etched substrates, in accordance with an embodiment of the invention. The semiconductor processing system 100 includes a factory interface 110, a central transfer chamber 120, a plurality of etch chambers 130 and a plurality of post-etch treatment chambers 140.

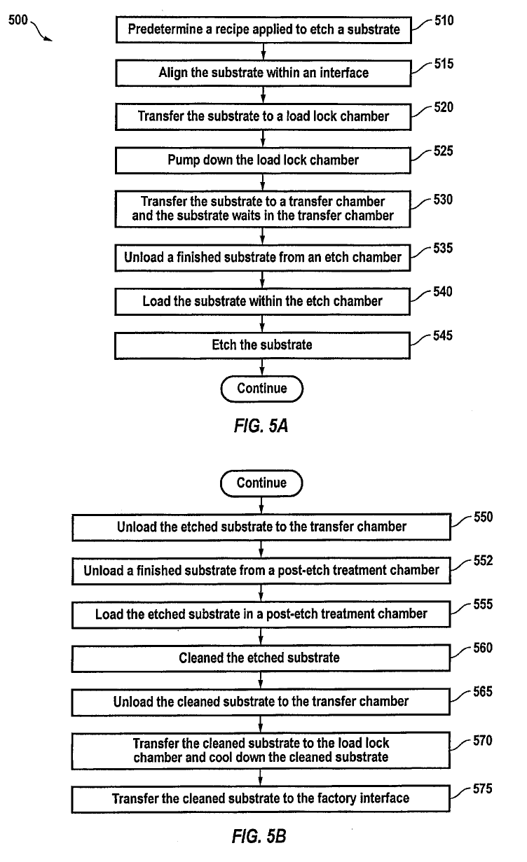

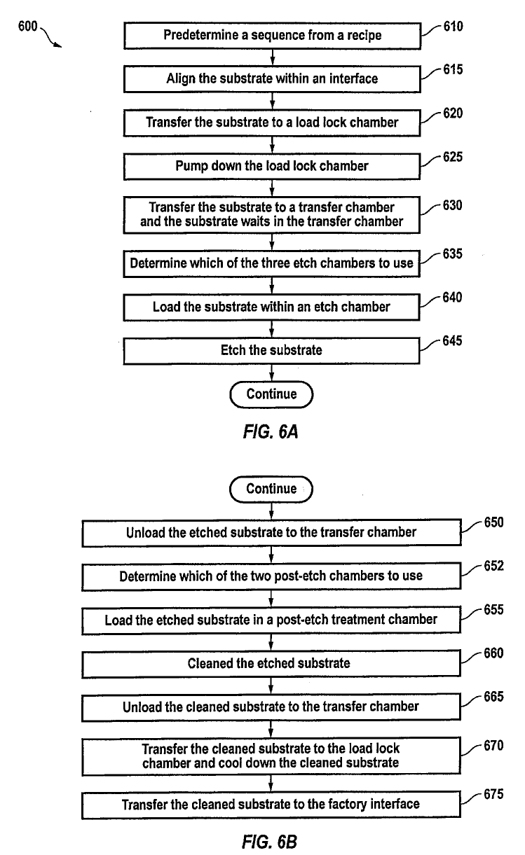

The factory interface 110 is coupled to the central transfer chamber 120. The plurality of etch chambers 130 and the plurality of post-etch treatment chambers 140 are coupled to the central transfer chamber 120. In some embodiments, a vacuum pump (not shown) is coupled to each of the central transfer chamber 120, the etch chambers 130 and the post-etch treatment chambers 140. In other embodiments, the temperatures of the central transfer chamber 120, the etch chambers 130 and the post-etch treatment chambers 140 are separately controlled. Power to each of the central transfer chamber 120, the etch chambers 130 and the post-etch treatment chambers 140 can be individually applied and controlled. A robot is configured to transfer substrates among the central transfer chamber 120, the etch chambers 130 and the post-etch treatment chambers 140. In other embodiments, one gate is coupled to each of the central transfer chamber 120, the etch chambers 130 and the post-etch treatment chambers 140. The gates are configured to provide access to the central transfer chamber 120, the etch chambers 130 and the post-etch treatment chambers 140 by opening or closing. The gates can be individually operated to open and/or close the central transfer chamber 120, the etch chambers 130 and the post-etch treatment chambers 140. In some embodiments, one pump is coupled to the central transfer chamber 120, the etch chambers 130 and/or the post-etch treatment chambers 140. However in other embodiments, one pump is coupled to each of the central transfer chamber 120, the etch chambers 130 and the post-etch treatment chambers 140. Wafers are transferred between the different chambers where they are undergo several processes, as described in further detail below with reference to FIGS. 5A-6B.

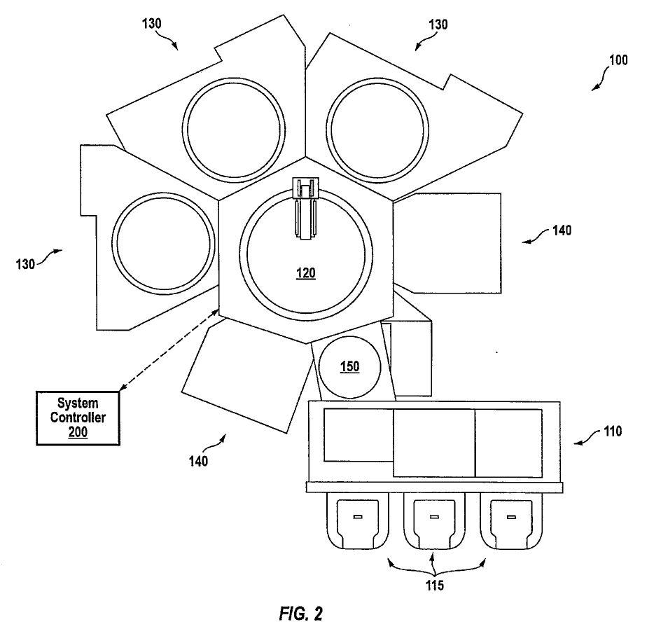

FIG. 2 is a schematic top view of the exemplary semiconductor processing system 100 described above with reference to FIG. 1 including the factory interface 110, ports 115 (3 shown), a central transfer chamber 120, a plurality of etch chambers 130, a plurality of post-etch treatment chambers 140, a substrate 150, and system controller 200. The factory interface 110 shows three ports 115 used to load and unload substrates into the semiconductor processing system 100. Those skilled in the art will realize that the number of ports 115 is not limited to the number of ports illustrated in FIG. 2 and can vary from one to more than three depending on specific application of the invention. Ports 115 can be configured to load substrates (or wafers) 150 stored in various containers including wafer cassettes and/or front open unified pods (FOUPs).

In some embodiments, at least one robot (not shown) can be configured within the factory interface 110 to transfer the substrate 150 among the factory interface 110 and the ports 115. The robot within the factory interface 110 is referred to as a hand-off system.

The substrate 150, which is provided to the semiconductor processing system 100, can vary depending on the application of the invention. For example, if the semiconductor processing system 100 is configured to etch a gate for a transistor, then the substrate 150 maybe a silicon substrate having oxide layer that has undergone nitradation and has a polysilicon layer deposited on top of it. The etch chambers 130 can then be used to etch the gate patterns in the polysilicon layer and the post-etch treatment chambers 140 can then be used to clean the etch residue. Those skilled in the art will realize that there are other applications which include using different incoming substrates 150. For example, substrate 150 could be a silicon substrate, a III-V compound substrate, a silicon/germanium (SiGe) substrate, an epi-substrate, a silicon-on-insulator (SOI) substrate, a display substrate such as a liquid crystal display (LCD), a plasma display, an electro luminescence (EL) lamp display, or a light emitting diode (LED) substrate, for example. In some embodiments, the substrate 150 may be a semiconductor wafer of various sizes (e.g., a 200 mm, 300 mm, 400 mm, etc. silicon wafer).

The central transfer chamber 120, which is coupled to the factory interface 110, is configured so that the substrate 150 can be transferred from the factory interface 110 to the etch chambers 130 or the post-etch treatment chambers 140, or from the etch chambers 130 or the post-etch treatment chambers 140 to the factory interface 110, or from the etch chambers 130 to the post-etch treatment chambers 140, or from the post-etch treatment chambers 140 to the etch chambers 130. Although not shown in FIG. 2, the transferring chamber 120 can include at least one robot.

The Etch chambers 130 can be used to etch various materials including metals or dielectrics. If the etch chambers 130 are configured to etch metallic structure formed over the substrate 150, then the etch chamber will be configured to etch materials including, for example, aluminum-containing material such as aluminum, aluminum copper, aluminum silicon copper, other aluminum-containing material or various combinations thereof, tungsten, titanium, titanium nitride; tantalum, tantalum nitride, copper-containing material or other metallic material. The etch chambers 130 can also be configured to etch aluminum-containing metallic layers formed over flash memories, DRAM memories and/or logic circuits. Etching of aluminum-containing materials can be done using halogen-containing etch gasses, such as chlorine. Some examples of etch chambers 130 include AdvantEdge™ etch chambers, decoupled plasma source (DPS™) etch chambers and DPS II™ etch chambers, all of which are commercially available from Applied Materials, Inc., Santa Clara, Calif.

In some embodiments, the post-etch treatment chambers 140 are configured to remove etch residues, etch byproducts and/or photoresist formed for patterning the metallic layer described above. The post-etch treatment chambers 140 may be configured to remove halogen-containing residues, such as chlorine-containing residues and/or photoresist. The post-etch treatment chambers 140 can be referred to as strip and passivation chambers. In some embodiments, the post-etch treatment chambers 140 can include at least one of Axiom™ chambers, Advanced Strip and Passivation (ASP™) and ASP II™ modules, commercially available from Applied Materials, Inc., Santa Clara, Calif.

The system controller 200 is generally designed to facilitate the control and automation of the overall system and typically includes a central processing unit (CPU) (not shown), memory (not shown), and support circuits (or I/O) (not shown). The CPU may be one of any kind of computer processors that are used for controlling various system functions including controlling chamber processes and support hardware (e.g., detectors, robots, motors, gas sources hardware, etc.) or monitoring systems and chamber processes (e.g., chamber temperature, process sequence throughput, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor. The support circuits may include cache, power supplies, clock circuits, input/output circuitry, subsystems, and the like. A program (or computer instructions) readable by the system controller 200 determines which tasks are performable on a substrate. Preferably, the program is software readable by the system controller 200 that includes code to perform tasks relating to monitoring, control and execution of the processing sequence tasks and various chamber recipe processes.

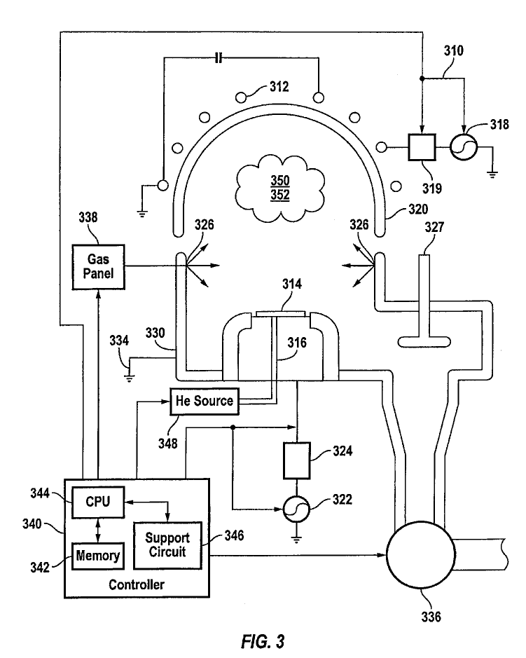

FIG. 3 depicts a schematic diagram of a DPS etch process chamber which can be incorporated into the semiconductor processing system 100 as the etch chamber 130, according to an embodiment of the invention. A DPS chamber 310 can include at least one inductive coil antenna segment 312, positioned exterior to a dielectric, dome-shaped ceiling 320 (referred to herein as the dome 320). Other chambers may have other types of ceilings, e.g., a flat ceiling. Antenna segment 312 can be coupled to a radio-frequency (RF) source 318 (that is generally capable of producing an RF signal having a tunable frequency). RF source 318 is coupled to antenna 312 through a matching network 319. DPS chamber 310 can include a substrate support pedestal (cathode) 316 that is coupled to a second RF source 322 that is generally capable of producing an RF signal. RF source 322 can be coupled to cathode 316 through a matching network 324. DPS chamber 310 can also contain a conductive chamber wall 330 that is connected to an electrical ground 334. A controller 340 including a central processing unit (CPU) 344, a memory 342, and support circuits 346 for a CPU 344 is coupled to various components of DPS etch process chamber 310 to facilitate control of the etch process.

In operation, a semiconductor substrate 314 is placed on substrate support pedestal 316 and gaseous components are supplied from a gas panel 338 to DPS chamber 310 through entry ports 326 to form a gaseous mixture 350. Gaseous mixture 350 is ignited into a plasma 352 in DPS chamber 310 by applying RF power from RF sources 318 and 322 respectively to antenna 312 and cathode 316. The pressure within the interior of DPS chamber 310 is controlled using a throttle valve 327 situated between DPS chamber 310 and a vacuum pump 336. The temperature at the surface of chamber walls 330 is controlled using liquid-containing conduits (not shown) that are located in walls 330 of DPS chamber 310.

The temperature of substrate 314 is controlled by stabilizing the temperature of support pedestal 316 and flowing helium gas from a source 348 to channels formed by the back of substrate 314 and grooves (not shown) on the pedestal surface. The helium gas is used to facilitate heat transfer between pedestal 316 and substrate 314. During the etch process, substrate 314 is heated by a resistive heater within the pedestal to a steady state temperature and the helium facilitates uniform heating of substrate 314. Using thermal control of both dome 320 and pedestal 316, substrate 314 is maintained at a temperature of between about 100° C. and about 500° C. Examples of the etch chambers 130 that can be used with exemplary methods of the invention may include those shown and described in co-assigned U.S. Patent Publication No. 2007/0077767 to Jin et al., filed Aug. 14, 2006, and titled “METHOD OF PLASMA ETCHING OF HIGH-K DIELECTRIC MATERIALS,” the entire contents of which is hereby incorporated by reference for all purposes.

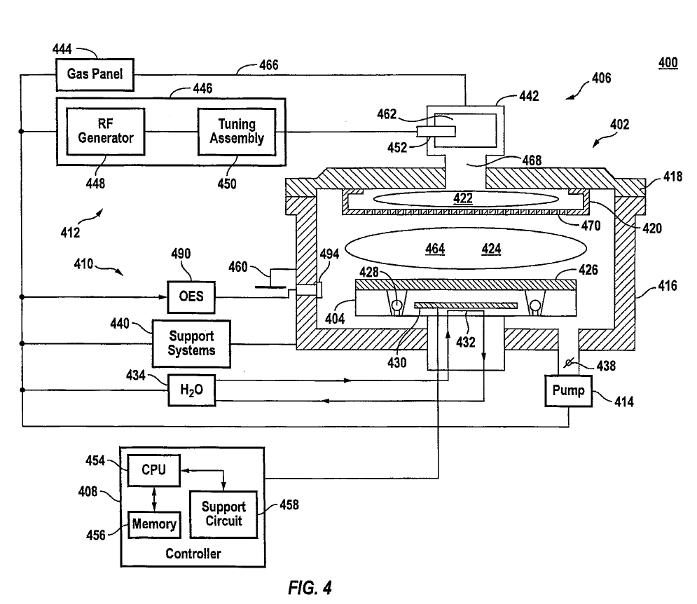

FIG. 4 depicts a schematic diagram of a post-etch treatment chamber 400 which can be incorporated into the semiconductor processing system 100, as the post-etch treatment chamber 140 described above with reference to FIG. 1, in accordance with an embodiment of the invention. The post-etch treatment chamber 400 can include a process chamber 402, a remote plasma source 406, and a controller 408.

Process chamber 402 generally is a vacuum vessel that includes a first portion 410 and a second portion 412, where the first portion 410 includes a substrate pedestal 404, a sidewall 416, and a vacuum pump 414 and the second portion 412 includes a lid 418 and a gas distribution plate (showerhead) 420, which defines a gas mixing volume 422 and a reaction volume 424. Lid 418 and sidewall 416, which are generally formed from a metal (e.g., aluminum (Al), stainless steel, and the like), are electrically coupled to a ground reference 460. Sidewall 416 includes a window 494 (quartz) that is used to monitor the optical emissions within the plasma. Window 494 is coupled to a light-collecting device 492 that carries the optical signals to a optical emission spectroscopy (OES) system 490. Substrate pedestal 404 supports a substrate (wafer) 426 within reaction volume 424. In one embodiment, substrate pedestal 404 can include a source of radiant heat, such as gas-filled lamps 428, as well as an embedded resistive heater 430 and a conduit 432. Conduit 432 provides cooling water from a source 434 to the backside of substrate pedestal 404. Substrate 426 sits on pedestal 404 by gravity or, alternatively, can be mechanically clamped, vacuum clamped, or electrostatically clamped as in an electrostatic chuck. Gas conduction transfers heat from pedestal 404 to substrate 426. The temperature of substrate 426 may be controlled between about 20° C. and about 400° C. Vacuum pump 414, which is used to maintain a desired gas pressure in process chamber 402, as well as evacuate the post-processing gases and other volatile compounds from process chamber 40, is coupled to a throttle valve 438 to control the gas pressure in process chamber 402 and to an exhaust port 436 formed in sidewall 416 of process chamber 402. Process chamber 402 can also include conventional systems for retaining and releasing substrate 426 and internal diagnostics, which are collectively depicted in FIG. 4 as support system 440.

Remote plasma source 406 includes a power source 446, a gas panel 444, and a remote plasma chamber 442. In one embodiment, power source 446 includes a radio-frequency (RF) generator 448 capable of producing of about 200 W to about 5000 W at a frequency of about 200 kHz to about 600 kHz, a tuning assembly 450, and an applicator 452 that is inductively coupled to remote plasma chamber 442 and energizes a process gas (or gas mixture) 462 to plasma 464 in the chamber. Gas panel 444, which can include mass flow controllers and shut-off valves to control gas pressure and flow rate, uses a conduit 466 to deliver process gas 462 to the remote plasma chamber 442. Plasma 464, is made up of process gas 462 that have been ionized and dissociated to form reactive species. The reactive species are directed into mixing volume 422 through inlet port 468 in lid 418. To minimize charge-up plasma damage to devices on substrate 426, the ionic species of process gas 462 are substantially neutralized within mixing volume 422 before the gas reaches reaction volume 424 through a plurality of openings 470 in showerhead 420.

Controller 408 includes a central processing unit (CPU) 454, a memory 456, and a support circuit 458. CPU 454 can be a general-purpose computer processor used in an industrial setting and memory 456 can be storage devices such as random access memory, read only memory, floppy or hard disk, or other form of digital storage used to store software routines. Support circuits 458 can include cache, clock circuits, input/output sub-systems, power supplies, and the like.

The window port 494, which is used for attaching light-collecting device 492 (e.g., a fiber optic probe and cable) to monitor plasma intensity, is located slightly above the substrate plane for collecting emission intensity along a line parallel to the substrate. Optical emission spectroscopy hardware 490, used to analyze the plasma and process is coupled to the window port 494.

Referring again to FIG. 2, one of the etch chambers 130 processes the substrate 150 for a first processing time. In some embodiments, the first processing time can be between about 75 seconds and about 225 seconds. In one specific embodiment, the first processing time can be about 120 seconds. One of the post-etch treatment chambers 140 can process the substrate 150 for a second processing time between about 50 seconds and about 150 seconds. In one specific embodiment, the second processing time can be about 80 seconds. A ratio of the number of the etch chambers 130 to the number of the post-etch treatment chambers 140 is substantially proportional to a ratio of the first processing time to the second processing time. For example, the first processing time is about 120 seconds and the second processing time is about 80 seconds. The ratio of the first processing time to the second processing time is about 3:2. In this example, the number of the etch chambers 130 may be 3, 6, 9, etc and the number the post-etch treatment chambers 140 may be 2, 4, 6, etc. Since the ratio of the first processing time to the second processing time is substantially proportional to the ratio of the number of the etch chambers 130 to the post-etch treatment chambers 140, substrates processed by the etch chambers 130 can be desirably transferred to the post-etch treatment chambers 140 without substantially idling. Accordingly, a desired throughput or efficiency of the semiconductor processing system can be achieved.

It is noted that the first and second processing times and the numbers of the etch chambers 130 and the post-etch treatment chambers 140 are not limited to the exemplary embodiments described above. Various ratios of the first processing time to the second processing time can be used. Other ratios, processing times and numbers of the etch chambers 130 and the post-etch treatment chambers 140 can be applied in other embodiments. One of ordinary skill in the art, based on the exemplary embodiments set forth above, can modify the ratio to achieve a desired manufacturing throughput.

In some embodiments, the etch chambers 130 may be configured to clean the substrate 150 before and/or after the etch process. The cleaning process may have a processing time between about 10 seconds and about 60 seconds. In one specific embodiment, the cleaning process may have a processing time of about 30 seconds. In some embodiments, a time for transferring the substrate 150 between the etch chambers 130 and the central transfer chamber 120 can be between about 10 seconds and 20 seconds. In one specific embodiments, a time for transferring the substrate 150 between the etch chambers 130 and the central transfer chamber 120 can be about 5 seconds. In some embodiments, a time for transferring the substrate 150 between the post-etch treatment chambers 140 and the central transfer chamber 120 can be between about 5 seconds and about 20 seconds. In one specific embodiment, a time for transferring the substrate 150 between the post-etch treatment chambers 140 and the central transfer chamber 120 can be about 10 seconds.

The central transfer chamber 120 may have a level of vacuum that is substantially equal to at least one of the etch chambers 130 and the post-etch treatment chambers 140. With the substantially similar vacuum among the central transfer chamber 120, the etch chambers 130 and the post-etch treatment chambers 140, the pumping process for substantially equalizing the pressures within the central transfer chamber 120, the etch chambers 130 and the post-etch treatment chambers 140 may be saved. By removing the pumping time the throughput is increased. In some embodiments, the substrate 150 is transferred between the central transfer chamber 120, the etch chambers 130 and the post-etch treatment chambers 140, which have substantially similar vacuum levels, such that the substrate 150 is not exposed to the atmosphere. The issue of corrosion and/or contamination of the substrate 150 due to the exposure may be desirably avoided.

FIGS. 5A-5B illustrate a flowchart of a method for processing a substrate within a semiconductor processing system 100, according to an embodiment of the invention. The method 500 begins with process 510, where a recipe for processing the substrates in the semiconductor processing system 100 (shown in FIG. 1) is selected. For example, if the semiconductor processing system 100 has three etching chambers 130 and two post-etch treatment chambers 140, the recipe selected in process 510 will including processing substrates through the etch chamber 130 and the post-etch treatment chamber 140. After the recipe is selected in process 510, the semiconductor processing system 100 begins processing the substrate according to the selected process recipe. In process 515 the substrate is aligned within the factory interface 110 (shown in FIG. 1). After aligning the substrate, the substrate is transferred to a load lock chamber, in process 520. Next in process 525, the pressure within the load lock chamber is reduced by pumping out the air with the use of a pump. In process 530, the substrate is transferred to a transfer chamber and waits in the transfer chamber. Next in process 535 a finished substrate is unloaded from an etching chamber, so that the substrate waiting in the transfer chamber can be loaded. It is noted that process 535 can be optional if the etching chamber is available for processing. The substrate is then loaded into the etching chamber in process 540. The substrate is then etched in the etching chamber in process 545.

FIG. 5B is a flow chart continuing where FIG. 5A ended. After the substrate is etched in process 545, the etched substrate is unloaded from the etching chamber into the transfer chamber, in process 550. Next in process 552, a substrate that has been processed in the post-etch treatment chamber is unloaded from the post-etch treatment chamber, so that the etched substrate waiting in the transfer chamber can be loaded into the post-etch treatment chamber for processing. It is noted that process 552 can be optional if the etching chamber is available for processing. The etched substrate is then loaded into a post-etch treatment chamber in process 555. Next in process 560, the etched substrate is cleaned within the post-etch treatment chamber. After cleaning the etched substrate, the cleaned substrate is then unloaded from the post-etch treatment chamber into the transfer chamber in process 565. Next in process 570, the cleaned substrate is transferred from the transfer chamber to the load lock chamber and cooled down in the load lock chamber. In process 575 the cleaned substrate is then transferred to factory interface 110, where the cleaned substrate is placed into a wafer cassette or a FOUP. It is noted that the processes shown in the flowchart are included in an embodiment. The scope of the invention, however, is not limited thereto. One of ordinary skill in the art can modify the flowchart to desirably reduce the processing time.

FIGS. 6A-6B illustrate a flowchart of a method of processing a substrate within a semiconductor processing system 100, according to another embodiment of the invention. The method 600 begins with process 610, where a recipe for processing the substrates in the semiconductor processing system 100 (shown in FIG. 1) is selected. For example, if the semiconductor processing system 100 includes three etching chambers 130 and two post-etch treatment chambers 140, the recipe selected in process 610 will include process processing substrates through the etch chamber 130 and the post-etch treatment chamber 140. After the recipe is selected in process 610, the semiconductor processing system 100 begins processing the substrate according to the selected process recipe. In process 615 the substrate is aligned within the factory interface 110 (shown in FIG. 1). After aligning the substrate, the substrate is transferred to a load lock chamber, in process 620. Next in process 625, the pressure within the load lock chamber is reduced by pumping out the air with the use of a pump. In process 630, the substrate is transferred to a transfer chamber and waits in the transfer chamber. Next in process 635, the availability of each etch chamber 130 is determined. If none of etch chambers 130 are available, then the substrate is held in the transfer chamber until one of etch chambers 130 becomes available. In embodiments, method 600 can include a look-ahead function for process 635. In another embodiment, one of etch chambers 130 is determined so as to desirably optimize the process time of method 600. After it is determined in process 635 that an etch chamber is available, the substrate is loaded in the etching chamber in process 640. Next in process 645, the substrate is etched in the etching chamber according the recipe selected in process 610.

FIG. 6B is a flow chart continuing where FIG. 6A ended. After the substrate is etched in process 645, the etched substrate is unloaded from the etching chamber into the transfer chamber, in process 650. Next in process 652, the substrate that has been processed in the post-etch treatment chamber is unloaded from the post-etch treatment chamber, so that the etched substrate waiting in the transfer chamber can be loaded into the post-etch treatment chamber for processing. If none of post-etch treatment chambers 140 are available, the substrate is held in the transfer chamber until one of post-etch treatment chambers 140 is available. In embodiments, method 600 can include a look-ahead function for process 652. In another embodiment, one of post-etch treatment chambers 140 is determined so as to desirably optimize the process time of method 600. After process 652, the etched substrate is then loaded into a post-etch treatment chamber in process 655. The etched substrate is then cleaned within the post-treatment chamber in process 660. After cleaning the etched substrate, the cleaned substrate is then unloaded from the post-treatment chamber to the transfer chamber in process 665. Next in process 670, the cleaned substrate is transferred from the transfer chamber to the load lock chamber and cooled down in the load lock chamber. In process 675 the cleaned substrate is then transferred to factory interface 110, where the cleaned substrate is placed into a wafer cassette or a FOUP. It is noted that the processes shown in the flowchart merely describe an embodiment. The scope of the invention, however, is not limited thereto. One of ordinary skill in the art can modify the flowchart to desirably reduce the processing time.

Having described several embodiments, it will be recognized by those of skill in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a method” includes a plurality of such methods and reference to “the precursor” includes reference to one or more precursors and equivalents thereof known to those skilled in the art, and so forth.

Also, the words “comprise,” “comprising”, “include”, “including”, and “includes” when used in this specification and in the following claims are intended to specify the presence of stated features, integers, components, or processes, but they do not preclude the presence or addition of one or more other features, integers, components, processes, acts, or groups.

What is claimed is:

1. A semiconductor processing system, comprising:
a factory interface;
a central transfer chamber coupled to the factory interface;
a first number of etch chambers coupled to the central transfer chamber, the first number of etch chambers being configured to etch a substrate at about a first processing time; and
a second number of post-etch treatment chambers coupled to the central transfer chamber, the second number of post-etch treatment chambers being configured to process the substrate at about a second processing time, wherein a ratio of the first number to the second number is substantially proportional to a ratio of the first processing time to the second processing time.

2. The semiconductor processing system of claim 1 further comprising at least one robot configured to transfer the substrate between the factory interface and the transfer chamber.

3. The semiconductor processing system of claim 1, wherein a vacuum level within the central transfer chamber is substantially equal to a vacuum level within the etch chambers or the post-etch treatment chambers.

4. The semiconductor processing system of claim 1, wherein the first number is 3 and the second number is 2.

5. The semiconductor processing system of claim 1, wherein the first processing time is between about 75 seconds and about 225 seconds and the second processing time is between about 50 seconds and about 150 seconds.

6. The semiconductor processing system of claim 1, wherein the etch chamber are metal etch chambers.

7. The semiconductor processing system of claim 1, wherein the post-etch treatments chambers are configured to remove at least one of photoresist, etch residues and etch by-product.

8. The semiconductor processing system of claim 1, wherein the etch chambers are configured to clean the substrate.

9. The semiconductor processing system of claim 8, wherein a time for cleaning the substrate is between about 10 seconds and about 40 seconds.

10. A semiconductor processing system of claim 1, wherein the ratio of the first number to the second number is predetermined that the substrate is transferred among the etch chambers and the post-etch treatment chambers without substantially idling.

11. A semiconductor processing system, comprising:
a factory interface;
a central transfer chamber coupled to the factory interface;
at least one robot configured to transfer a substrate between the factory interface and the transfer chamber;
a first number of metal etch chambers coupled to the central transfer chamber, the first number of etch chambers being configured to etch the substrate at about a first processing time; and
a second number of post-etch treatment chambers coupled to the central transfer chamber, the second number of post-etch treatment chambers being configured to process the substrate at about a second processing time, wherein a ratio of the first number to the second number is substantially proportional to a ratio of the first processing time to the second processing time.

12. The semiconductor processing system of claim 11, wherein a vacuum level within the central transfer chamber is substantially equal to a vacuum level within the metal etch chambers or the post-etch treatment chambers.

13. The semiconductor processing system of claim 11, wherein the first number is 3 and the second number is 2.

14. The semiconductor processing system of claim 11, wherein the first processing time is between about 75 seconds and about 225 seconds and the second processing time is between about 50 seconds and about 150 seconds.

15. The semiconductor processing system of claim 11, wherein the post-etch treatments chambers are configured to remove at least one of photoresist, etch residues and etch by-product.

16. The semiconductor processing system of claim 11, wherein the metal etch chambers are configured to clean the substrate.

17. The semiconductor processing system of claim 16, wherein a time for cleaning the substrate is between about 30 seconds and about 150 seconds.

18. A semiconductor processing system, comprising:
a factory interface;
a central transfer chamber coupled to the factory interface;
at least one robot configured to transfer a substrate between the factory interface and the transfer chamber;
three metal etch chambers coupled to the central transfer chamber, the etch chambers being configured to etch the substrate at about a first processing time; and
two post-etch treatment chambers coupled to the central transfer chamber, the post-etch treatment chambers being configured to process the substrate at about a second processing time.

19. The semiconductor processing system of claim 18, wherein a vacuum level within the central transfer chamber is substantially equal to a vacuum level within the metal etch chambers or the post-etch treatment chambers.

20. The semiconductor processing system of claim 18, wherein the first processing time is about 120 seconds and the second processing time is about 80 seconds.

21. The semiconductor processing system of claim 18, wherein the post-etch treatments chambers are configured to remove at least one of photoresist, etch residues and etch by-product.

22. The semiconductor processing system of claim 18, wherein the etch chambers are configured to clean the substrate for about 30 seconds.
